(19) United States
(12) Patent Application Publication
(10) Pub. No.: US 2019/0269040 A1
(43) Pub. Date: Aug. 29, 2019

(54) FUNCTION MODULE FOR BLADE SERVER

(71) Applicant: Cisco Technology, Inc., San Jose, CA (US)

(72) Inventors: Le GAO, Shanghai (CN); Yang SUN, Zhejiang (CN); Rudong SHI, Shanghai (CN); Na FENG, Shanghai (CN)

(21) Appl. No.: 15/908,648

(22) Filed: Feb. 28, 2018

(51) Int. Cl. H05K 7/20; H05K 7/14

(52) U.S. Cl. CPC H05K 7/20736; H05K 7/1492; H05K 7/1489

(57) ABSTRACT

The embodiments herein describe a function module that is removably mounted in a chassis. For example, the chassis may be a server chassis which stores a plurality of blade servers which uses hardware components and a fan module mounted in the function module to increase the storage capacity or computing performance of the blade servers. The function module can include PCIe cards, GPU cards, hard drives, and the like which are communicatively coupled to the blade servers in the chassis. In one embodiment, the function module is slidably mounted onto the chassis so that when pulled by the system administrator, the function module slides out of a front or rear side of the chassis. Doing so provides room for the system administrator to then add and/or remove the hardware components and the fan module mounted in the function module.

### TECHNICAL FIELD

Embodiments presented in this disclosure generally relate to a removable function module in a chassis for expanding computing capabilities.

### BACKGROUND

Storage and parallel computing performance are becoming more important in data centers that rely on servers and other computing devices. Hard drive arrays, graphics processing units (GPUs), and PCIe cards are commonly used to increase the storage and computing capabilities in blade servers. Overtime, a system administrator may want to change the configuration of the blades servers by upgrading the computing components in the server (e.g., replacing a current hard drive with a larger or faster or drive) or replacing faulty components (e.g., replacing a nonfunctional GPU with a functional GPU). However, accessing the servers can be difficult. For example, space within a server chassis is limited which means the computing components may be tightly packed in the chassis which requires the administrator to disassemble the chassis to access the components. For a blade server chassis, the rear side is mostly occupied by a fan module which means there is less space to add function modules using a rear panel. Further, data centers typically use racks to hold vertical stacks of servers. The system administrator may have to access a server that is at the top of the rack in order to upgrade or replace a hardware component, which can be dangerous.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates removable function modules in a chassis, according to one embodiment described herein.

FIG. 2 illustrates removing a function module from a chassis, according to one embodiment described herein.

FIG. 3 is an exploded view of an expansion unit in a chassis, according to one embodiment described herein.

FIG. 4 illustrates GPU cards mounted in the function module, according to one embodiment described herein.

FIG. 5 illustrates PCIe cards mounted in the function module, according to one embodiment described herein.

FIG. 6 illustrates hard drives mounted in the function module, according to one embodiment described herein.

FIG. 7 illustrates a side of a cage in the function module containing access slots, according to one embodiment described herein.

FIG. 8 illustrates a rack supporting multiple chassis, according to one embodiment described herein.

FIG. 9 is flowchart for hot swapping components using a function module, according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

### Overview

One embodiment presented in this disclosure is a chassis that includes a computing device and an expansion unit. The expansion unit includes a function module comprising a cage that supports one or more pluggable hardware components and a fan configured to cool the pluggable hardware components, a slide coupled to the cage, and a cable coupled to the function module where a length of the cable permits the one or more pluggable hardware components to communicate with the computing device when the function module is slid out from the chassis.

Another embodiment in this disclosure is a method that includes removing a cover to access an expansion unit disposed in a chassis where the expansion unit comprises a cage that supports one or more pluggable hardware components and a fan configured to cool the pluggable hardware components, a slide mounted to the chassis and to the cage, and a cable coupled to the function module. The method includes sliding the function module out of the chassis where the function module remains connected to the cable to permit the one or more pluggable hardware components to communicate with a computing device in the chassis when the function module is slid out from the chassis. The method includes adding at least one pluggable hardware component to the function module.

### Example Embodiments

The embodiments herein describe a function module that is removably mounted in a chassis. For example, the chassis may be a server chassis which stores a plurality of blade servers which uses pluggable hardware components mounted in the function module to increase the storage capacity or computing performance of the blade servers. The function module can include PCIe cards, GPU cards, hard drives, and the like which are communicatively coupled to the blade servers in the chassis.

In one embodiment, the function module is accessible by removing or opening a panel on the chassis. For example, the function module may be arranged near the front or rear of the chassis such that when the chassis is mounted on a rack, a system administrator can easily access the function module at either the front side or rear side of the rack. In one embodiment, the function module is slidably mounted in the chassis so that when pulled by the system administrator, the function module slides out of the chassis. Doing so provides room for the system administrator to add and/or remove the pluggable hardware components and a fan module mounted in the function module (e.g., hard drives, PCIe expansion cards, field programmable gate arrays (FPGA), GPUs, and the like). In one embodiment, the function module is coupled to the blade servers and power modules in the chassis using a flexible cable. When the function module is stored in the chassis, the cable is wound up or folded on itself. When the function module is slid out of the chassis, the extra slack in the cable can be used to maintain the data and power connection to the function module while the module is outside of the chassis. As such, the pluggable hardware components and the fan module in the function module can be hot swapped.

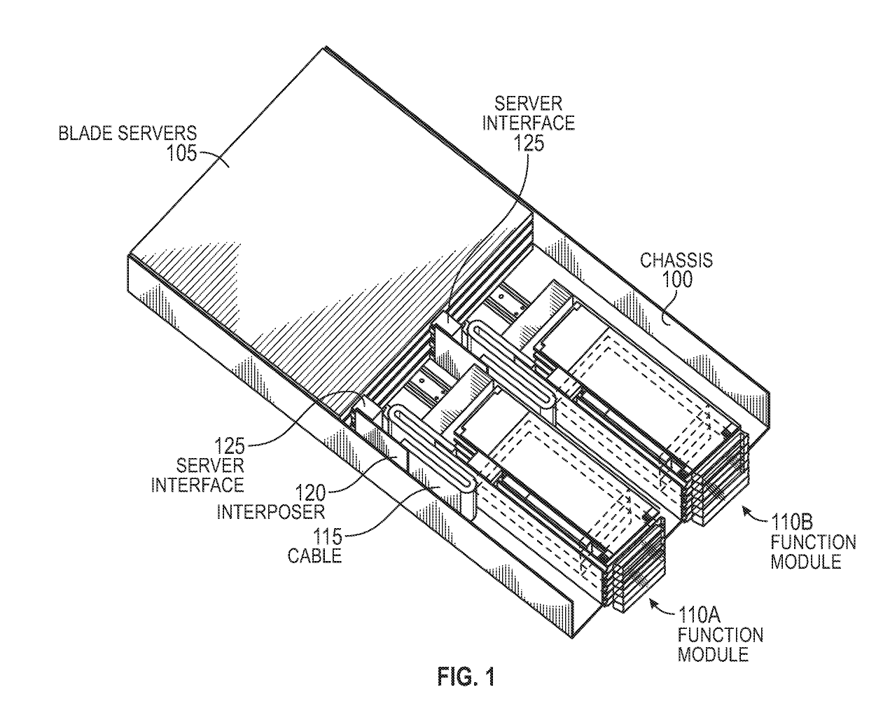

FIG. 1 illustrates removable function modules 110 in a chassis 100, according to one embodiment described herein. As shown, the chassis 100 defines a form factor which includes blade servers 105 and two function modules 110—i.e., function module 110A and 110B. Although not shown, the chassis 100 can also include power modules for powering the blade servers 105 and the function modules 110 as well as input/output (I/O) modules for connecting the blade servers to other servers or network devices (e.g., switches, routers, etc.). Further, the chassis 100 can include fans for cooling the blade servers 105 and the pluggable hardware components in function modules 110. In one embodiment, the power modules, I/O modules and the fans may be disposed on the side of the chassis opposite from the side containing the function modules 110.

For clarity, the top surface of the chassis 100 in FIG. 1 has been removed so that the components within the chassis 100 are viewable. Although FIG. 1 illustrates integrating the function modules 110 into the same chassis 100 that includes blade servers 105, the embodiments herein are not limited to such. The function modules 110 can be disposed in the chassis of any computing device where easy access to the hardware components in that device is desired. For example, the function modules 110 may be used in a network device to house different router cards. In another example, the function modules 110 may be used in a network storage device to store different hard drives. Moreover, although FIG. 1 illustrate disposing two function modules 110 in the chassis 100, the chassis 100 can contain only one function module 110, or three, four, five, etc. function modules 110.

The dimensions of the chassis 100 can vary depending on its use and the types of computing components mounted therein. For example, the chassis 100 may be used for a 6U server (where “U” is a standardized rack unit height measurement of 1.75 inches of 44.45 millimeters). A 6U server may have a height of around seven inches with a width around 17 to 18 inches. However, the height of the chassis 100 is reduced if it is a 5U, 4U or 2U server. Moreover, the dimensions may change if the chassis 100 is used to form a different computing system (e.g., a network router or network storage device).

Each function module 110 includes one or more pluggable hardware components which are communicatively coupled to the blade servers 105 using a cable 115, interposer 120, and a server interface 125. The hardware components can expand the storage or compute capabilities of the blade servers 105. For example, mounting hard drives in the blade servers 105 increases the amount of storage locally available to the blade servers 105 in the chassis 100. Mounting FPGAs in the function modules 110 permits a system administrator to customize programmable logic to perform a specific task. Mounting PCIe cards (such as a network interface card or an accelerator) can permit the blade servers 105 to offload special tasks to the PCIe cards that they may be able to perform faster than processors in the blade servers 105. GPUs can also be mounted in the function modules 110 to enable the blade servers 105 to offload specialized tasks such as rendering or machine learning which may increase the overall compute performance of the blade servers 105.

In one embodiment, the function modules 110A and 110B store the same type of pluggable hardware components. For example, both function modules 110A and 110B may contain hard drives. However, in another embodiment, the function modules 110A and 110B can have different types of hardware components. For example, the function module 110A may contain hard drives while the function module 110B contains PCIe cards. Further, each of the function modules 110 can have different hardware components. For example, the function module 110A can store both a hard drive and a GPU. The details of the function module are described in the Figures below.

The function modules 110 are communicatively coupled to the cable 115. That is, the cable 115 provides electrical wires or traces for transmitting data to, and from, the pluggable hardware components in the function modules 110. The cable 115 can include one, two, three, etc. different electrical wires which can be used to transmit data. For example, each hardware component (e.g., each GPU, PCIe card, or hard drive) in the function module 110 may have one or more dedicated or reserved data communication links in the cable 115. The function module 110 can use any high-speed data communication technique to transfer data using the wires in the cable 115. In addition to transmitting data, the cable 115 may deliver power to the function module 110 for powering the hardware components and fan modules.

FIG. 1 illustrates an arrangement of the cable 115 when the function module 110 is stored in the chassis 100. In this example, the cable 115 is folded on itself to form an “S” shaped arrangement. Doing so permits the cable 115 to have extra slack or length which can then be used when the function module 110 is slid out of the chassis 100. The extra slack in the cable 115 can be used to maintain the data and power connections to the function module 110 when the module 110 has been removed from the chassis 100. In other embodiments, the cable 115 may be wound up when the function module 110 is stored in the chassis 100.

The cable 115 is coupled to the function module 110 at one end and to the interposer 120 at the other end. In one embodiment, the interposer 120 is a printed circuit board (PCB) card which includes connections to the data and power wires in the cable 115. The interposer 120 may include internal traces or conductive paths to couple the cable 115 to the server interface 125. In one embodiment, the server interface 125 can selectively couple the blade servers 105 to the pluggable hardware components in the function module 110. For example, a first blade server 105 may want to use two of the hard drives in the function module 110A. The server interface 125 can use logic to selectively couple the first blade server to the desired hard drives. Later, if the first blade server 105 decides to communicate with a third hard drive, the logic in the server interface 125 can communicatively couple the first blade server 105 to the communication paths in the interposer 120 and the cable 115 which are used to communicate with the third hard drive in the function module 110A. However, in another embodiment, rather than permitting the blade servers 105 to communicate with any one of the hardware components in the function modules 110, specific hardware components can be assigned to a respective one of the blade servers 105. For example, the function module 110A may include four GPU cards where each card can be used (or is assigned) to only one of the four server blades 105 in the chassis 100. For example, depending on which slot the GPU cards are plugged into, the function module 110 may determine which blade server 105 can communicate with the card. That is, each of the blade servers 105 may be communicatively coupled to only one of the slots in the function module 110.

Although not shown, the blade servers 105 can include various hardware and software modules. For example, the blade servers 105 can include one or more processing elements which each can include any number of processing cores. Further, the blade servers 105 can include memory (e.g., DRAM or SRAM), caches, and the like. Using the processing elements and memory, the blade servers 105 can execute an operating system and user applications.

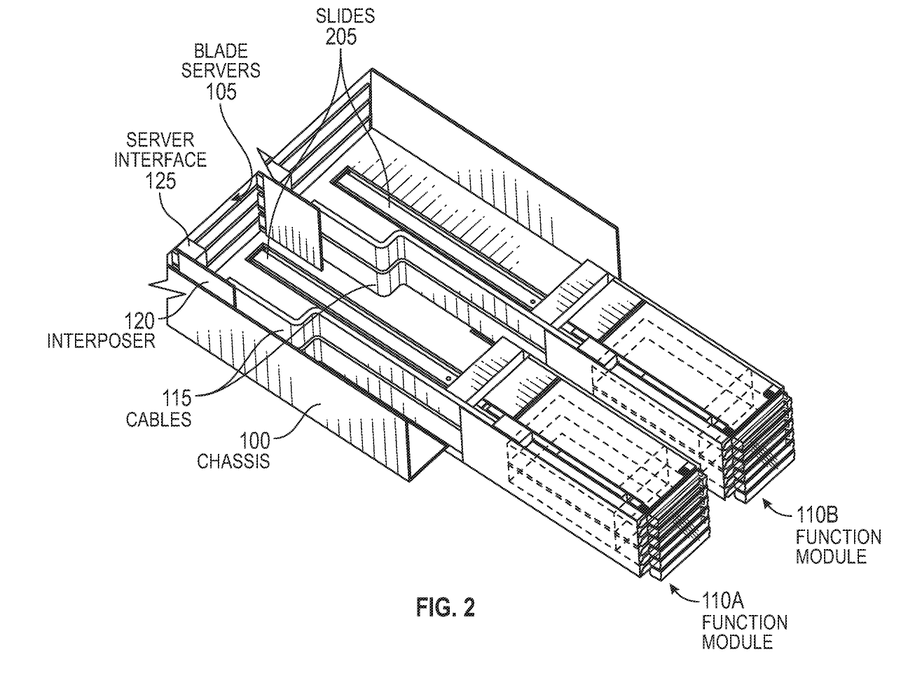

FIG. 2 illustrates removing the function modules 110 from the chassis 100, according to one embodiment described herein. As shown, both of the function modules 110 have been slid out from the volume defined by the chassis 100. For example, a system administrator may remove or flip down a removable cover to gain access to the function modules 110. The system administrator can then grab one (or both as is the case in FIG. 2) of the function modules 110 and pull the module 110 to remove it from the chassis 100. As shown here, the bottom surfaces of the function modules 110 are mounted onto respective slides 205 that permit the function modules 110 to be slid out from the chassis 100. In one embodiment, the slides 205 enable a bidirectional slidable movement allowing the functional modules 110 to be moved relative to the chassis 100. For example, a first portion of the slide 205 may be fixably mounted on the chassis 100 to form a track while a second portion of the slide 205 is fixably mounted on the function module 110. The first portion of the slide 205 (e.g., the track) can be a guide for the second portion of the slide 205 (e.g., a sliding member) which slides within the track when the function module 110 is pulled out from the chassis 100.

When the function modules 110 are slid out from the chassis 100, the cables 115 are unwound or straightened to maintain a data and power connection between the hardware components in the function module 110 and the blade servers 105 (or power supplies) in the chassis 100. That is, the slack in the cables 115 shown in FIG. 1 can be used to maintain communication between the function module 110 and the blade servers 105 when the function modules 110 have been removed from the chassis 100. This permits the hardware modules in the function modules 110 to be hot swapped.

The process can be reversed where a system administrator pushes on a function module 110 to slide the module back into the chassis 100. The cable 115 is then folded on itself or wound up to result in the arrangement illustrated in FIG. 1. In this manner, only the function modules 110 need to be removed from the chassis while the remaining components in the chassis 100 (and the chassis 100 itself) can remain stationary. For example, the chassis 100 can remain mounted on a rack while the function modules 110 can be slid out from a rear or front side of the chassis 100. Although the entire chassis 100 can be slidably mounted on the rack, the chassis 100 can be heavy which means sliding out the entire chassis 100 in order to access the internal hardware can cause a rack to tip, or break the slides.

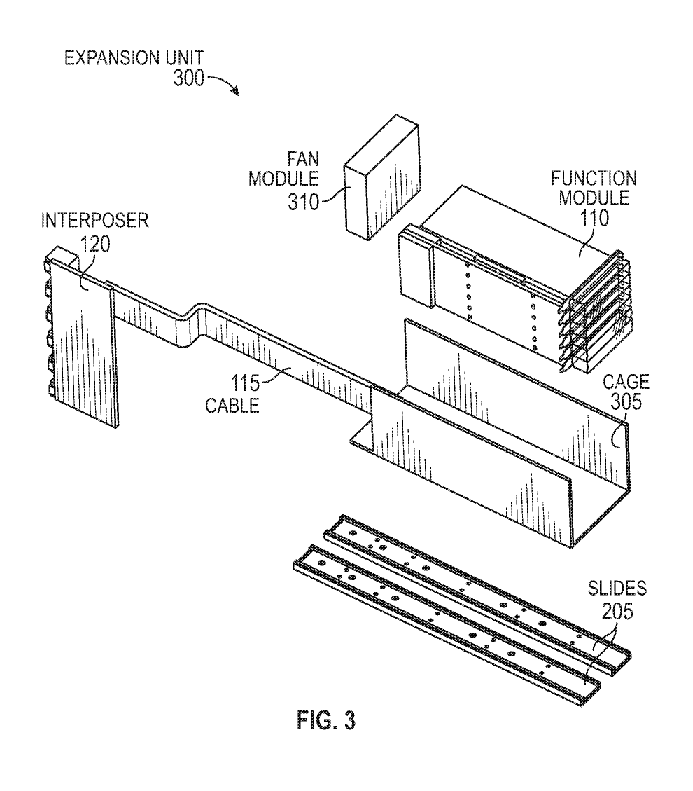

FIG. 3 is an exploded view of an expansion unit 300 in a chassis, according to one embodiment described herein. The expansion unit 300 includes the function module 110 as well as a cage 305, a fan module 310, the slides 205, the cable 115, and the interposer 120. That is, the expansion unit 300 includes the components used to slidably mount the function module 110 in the chassis and to provide data/power connections from the function module 110 to other hardware components in the chassis.

The cage 305 is a rigid structure on which the function module 110 is mounted. For example, the cage 305 may be formed from a metal or rigid plastic. In this example, the cage 305 includes a bottom surface and two raised side surfaces that form an enclosure for the function module 110. The function module 110 can be attached to the cage 305 using screws, rivets, clips, or other types of fasteners. As described in more detail below, only some of the components in the function module 110 are attached to the cage 305 while other components (e.g., the GPUs, FPGAs, PCIe cards, hard drive, or fans) can be removed. In one embodiment, the entire function module 110 is removable from the cage 305. For example, the function module 110 may include clips that attach it to the cage 305 which can be removed so the function module 110 can be lifted or slid out from the cage 305. The function module 110 may also be disconnected from the cable 115 using a socket or other connector.

The fan module 310 can also be mounted to the cage 305 such that the spatial relationship between the fan module 310 and the function module 110 is fixed. Moreover, when sliding out the function module 110, the fan module 310 can be replaced or repaired. The fan module 310 can include a fan, temperature sensors, and control logic for cooling the hardware components in the function module 110. For example, because the function module 110 may be disposed at an opposite end of the chassis from the fans used to cool the blade servers, the fan modules 310 can include fans specifically arranged on the cage 305 to cool the function module 110. That is, the cooling systems for the blade server may be insufficient for cooling the function modules 110 which is the job of the fan module 310. However, in other embodiments, the fan module 310 may be omitted from the expansion unit 300.

The slides 205 may be mounted to a bottom surface of the cage 305. In this example, the cage 305 may be mounted to two slides 205, but in other embodiments only one slide 205, or three slides 205, may be used. The cable 115 can also be attached to the cage 305, the function module 110, or both. As mentioned above, the cable 115 may have a plug that can be inserted into a receptacle in the function module 110 so that the cable 115 can be disconnected. In another embodiment, however, the cable 115 may be soldered or otherwise fixably attached to a PCB in the function module 110.

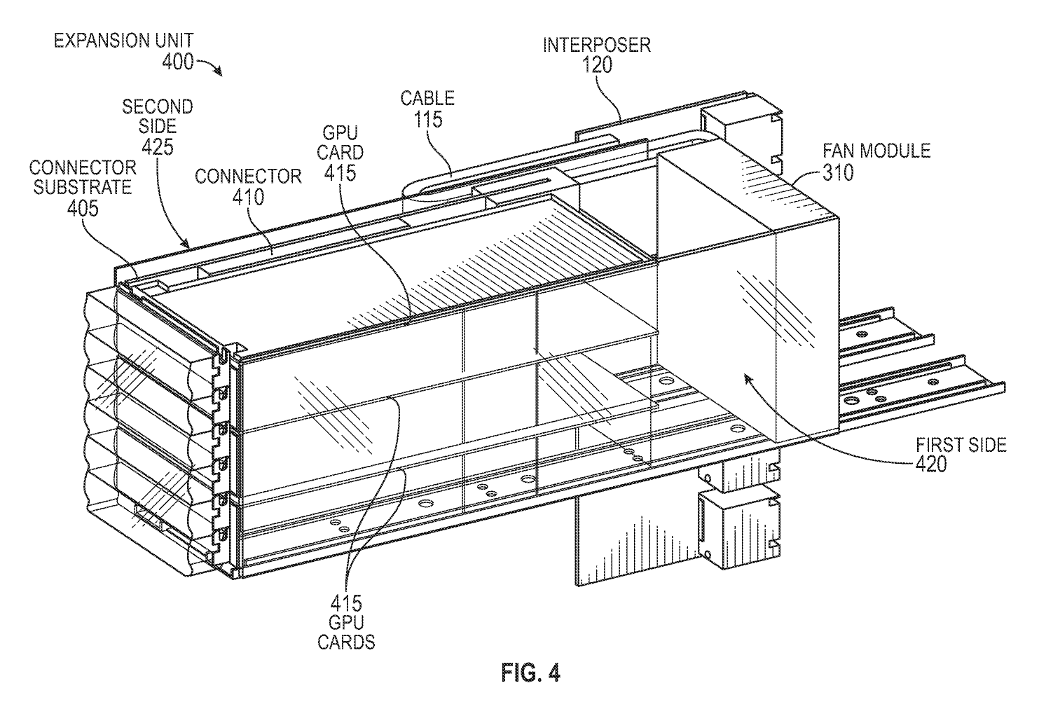

FIG. 4 illustrates GPU cards 415 mounted in the function module of an expansion unit, according to one embodiment described herein. The expansion unit 400 includes the interposer 120 and the cable 115 which connect the hardware components in the function module (e.g., the GPU cards 415) to the blade servers (not shown in FIG. 4). To do so, the function module includes a connector substrate 405 which is attached (either permanently or selectively) to a second side 425 of the cage. For example, the connector substrate 405 may be a PCB or other rigid substrate which can be mounted on the second side 425 of the cage.

In one embodiment, the cable 115 is communicatively coupled to the connector substrate 405 which includes traces or links for transmitting data and power to, and from, the cable 115. In addition, the connector substrate 405 includes connectors 410 which permit the GPU cards 415 to be plugged into the connector substrate 405. In one embodiment, the connectors 410 may be PCIe connectors or other type of high speed data connection. Moreover, the connectors 410 may include pins for transmitting power to the GPU cards 415. The connectors 410 provide structural support for the GPU cards which, in this example, are mounted horizontally in the function module (e.g., perpendicular to the second side 425). In one embodiment, the GPU cards 415 are double width, full height and length standard PCIe form factor GPU cards 415.

Using the connectors 410, a system administrator can add or replace the GPU cards 415 in the function module. For example, if one of the GPU cards fails, the system administrator can slide out the function module as shown in FIG. 2, disconnect the failed GPU card, and plug in a new GPU card in the connector 410. A similar process may be done when adding new cards or upgrading existing cards. For clarity, a first side 420 of the cage is transparent so that the GPU cards 415 can be seen. In one embodiment, the first side 420 may be spaced a sufficient distance from the GPU cards 415 so that the system administrator has room for removing and adding the GPU cards 415. However, in other embodiment, the system administrator may detach the connector substrate 405 from the second side 425 of the cage so that the connector substrate 405 along with the GPU cards 415 can be lifted out of the change. The system administrator can then replace or add GPU cards 415 to the connector substrate 405 before replacing the connector substrate 405 and the GPU cards 415 back into the cage.

In another embodiment, the connector substrate 405 may be mounted on the bottom surface of the cage instead of the second side 425 such that the connector substrate 405 is perpendicular to the direction shown in FIG. 4. As such, the GPU cards 415 when mounted to the connectors 410 are disposed vertically (e.g., parallel to the first and second sides 420, 425 rather than horizontally as shown). Doing so may make it easier for the system administrator to add or replace the GPU cards 415.

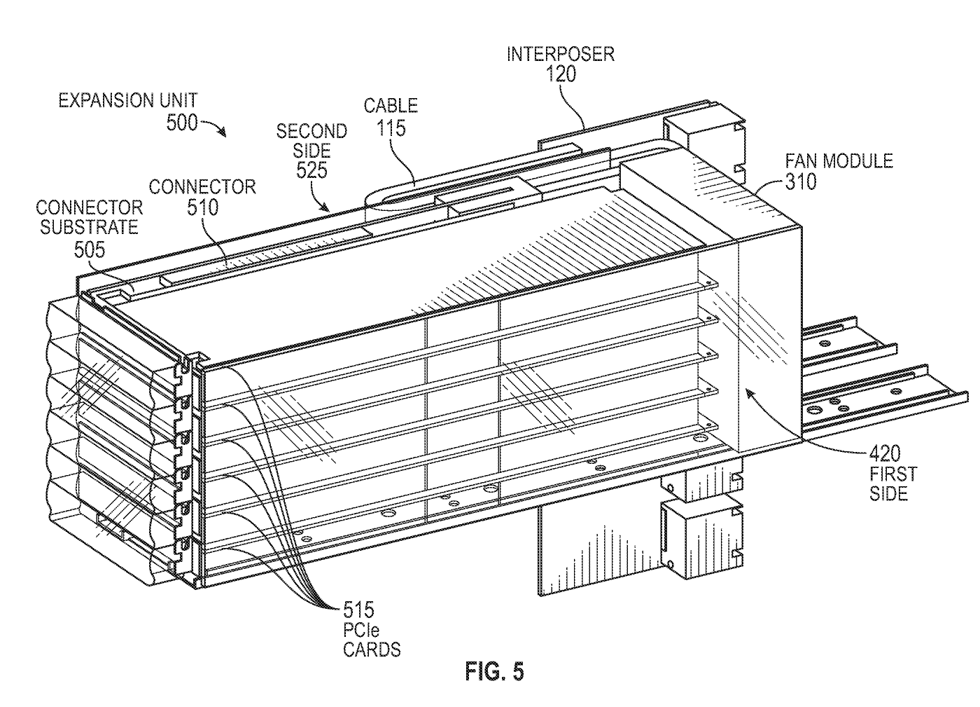

FIG. 5 illustrates PCIe cards 515 mounted in the function module of an expansion unit 500, according to one embodiment described herein. In one embodiment, the PCIe cards 515 may include six standard PCIe cards that can share the same back plane PCB (e.g., the connector substrate 505). The PCIe cards could include various hardware elements such as one or more processors, accelerators, FPGAs, and other components which can expand the computing capabilities of the blade servers in the same chassis.

The connector substrate 505, like the connector substrate 405 in FIG. 4, is mounted on the second side 425 of the cage (while the first side 420 is transparent) to provide structural support for the PCIe cards 515. In this example, the connector substrate 505 includes six connectors 510 for connecting to the PCIe cards 515. The connectors 510 provide structural support to the cards 515, communicatively couples the cards 515 to the blade servers, and can provide power to the cards 515 when the cards 515 are plugged into the connectors 510.

Moreover, although shown being mounted on the second side 425, the connector substrate 505 may be mounted on the bottom surface of the cage instead. Thus, the PCIe cards 515 can be plugged in either horizontally (as shown in FIG. 5) or vertically in the cage. Further, the system administrator can add or replace the PCIe cards when the connector substrate 505 remains in the cage, or first remove the substrate 505 (along with all the connector PCIe cards 515) before adding or replacing the cards 515 as discussed above.

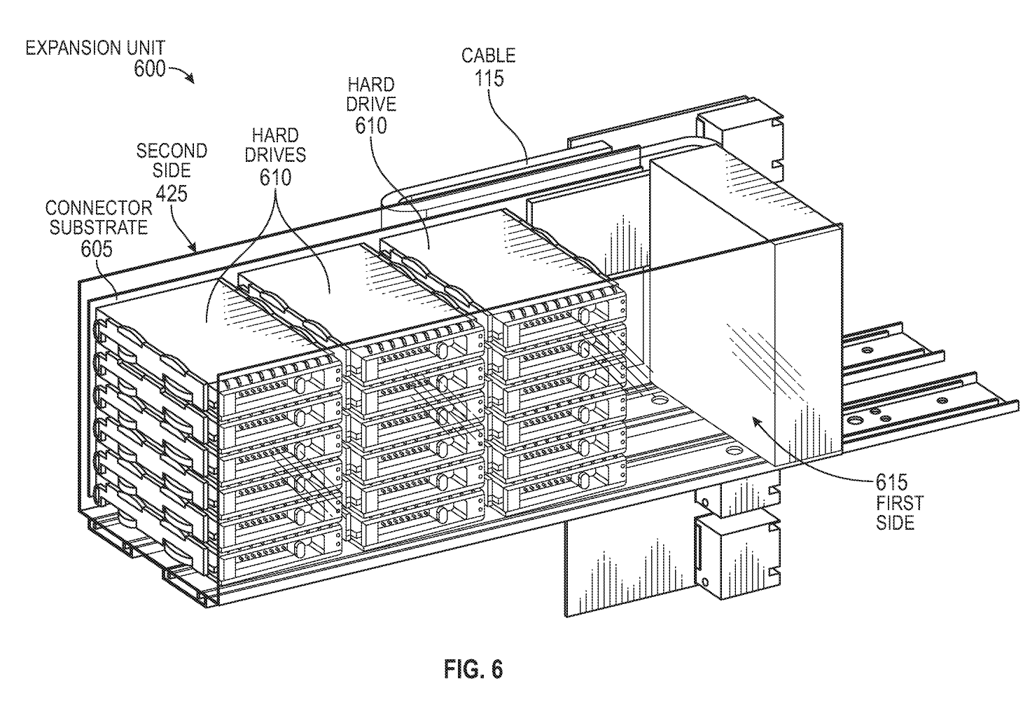

FIG. 6 illustrates hard drives 610 mounted in the function module in the expansion unit 600, according to one embodiment described herein. The expansion unit 600 includes a connector substrate 605 which communicatively couples the hard drives 610 to the cable 115 and to the blade servers as discussed above. The connector substrate 605 is mounted on the second side 425 but could be mounted on the bottom surface of the cage. In that case, the hard drives 610 may be arranged vertically in the cage rather than horizontally as shown in FIG. 6. Moreover, although not shown, the connector substrate may have a respective connector for each of the hard drives which communicatively couple the hard drives 610 to the blade servers and to power sources in the chassis using the cable 115 when the hard drives 610 are plugged in.

To replace or add hard drives 610, in one embodiment, the system administrator can remove the connector substrate 605 from the cage (which also removes the hard drives 610) and replace or add the hard drives 610 as desired. However, in another embodiment, the hard drives 610 may be spaced far enough from the first side 420 so that the system administrator can maneuver a hard drive 610 to a desired connector and then plug in the hard drive 610.

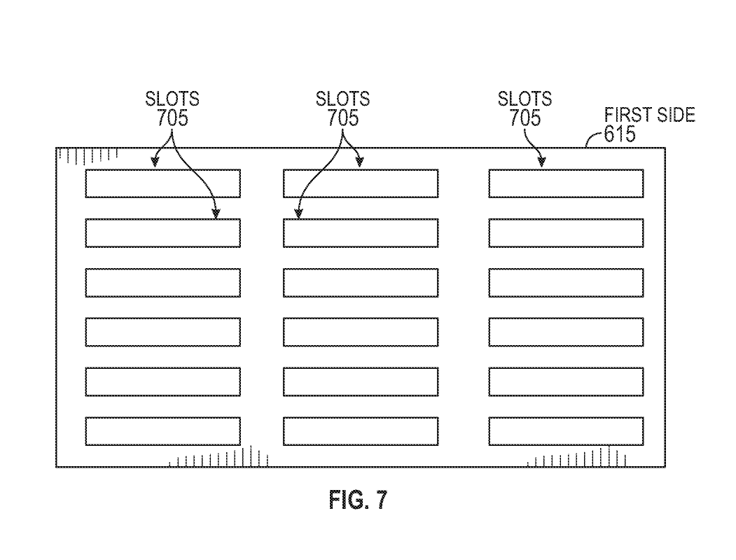

In one embodiment, the first side 615 includes slots that permit the hard drives 610 to be slid through the first side 615 to connect to, or disconnect from, the connector substrate 605. FIG. 7 illustrates the first side 615 containing access apertures which define slots 705, according to one embodiment described herein. The slots 705 have width and height dimensions at least equal to the width and thickness of the hard drives 610. It may be preferable to have dimensions greater than the hard drives 610 so that a system administrator can grasp the hard drives 610 through the slots 705 when disconnecting them from the connector substrate 605.

The first side 615 can contain as many slots 705 are there are connections in the connector substrate 605 for hard drives 610. Thus, the system administrator can slide out the expansion unit 600 and add or replace the hard drives without to removing the connector substrate 605. Further, the hard drives can be spaced closer to the first side 615 relative to an arrangement where the first side 615 does not have the slots 705 (e.g., is a single continuous sheet) since the slots 705 provide room for the administrator to add and remove the hard drives. As such, adding the slots 705 may reduce the dimensions of the expansion unit 600 and mean the connector substrate 605 can be fixably attached to the second side 425.

Although the slots 705 are shown for use with the hard drives 610, the first side 420 of the expansion units illustrated in FIGS. 4 and 5 can also have slots for adding or removing the GPU cards 415 or the PCIe cards 515. That is, in FIG. 4, the first side 420 may have three slots that align with the connectors 410 for the three GPU cards 415 in the connector substrate 405.

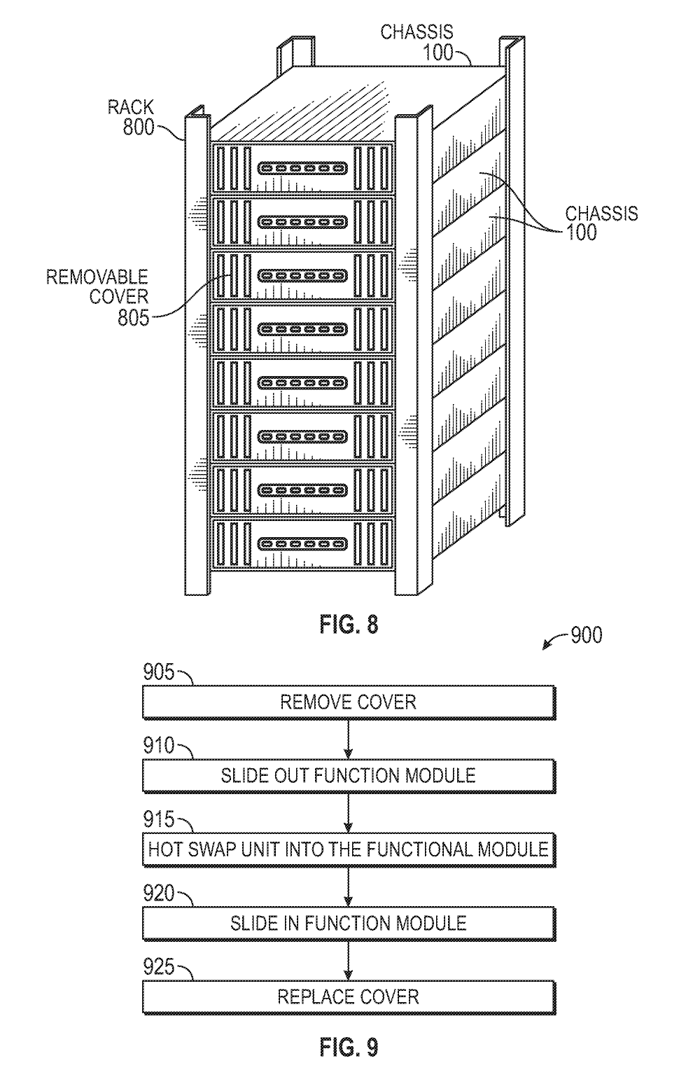

FIG. 8 illustrates a rack 800 supporting multiple chassis 100, according to one embodiment described herein. As shown, the chassis 100 are mounted horizontally in the rack 800. However, in another embodiment, the chassis 100 may be mounted vertically in the rack 800. For example, multiple chassis 100 may be stacked side-by-side vertically in the rack 800. In any case, each chassis 100 includes a removable cover 805 for accessing the function modules. As described above, in one embodiment, the function modules can be slid out from the chassis 100 once the removable covers 805 are opened or removed.

The removable covers 805 can be disposed on any side of the rack 800, although it may be more convenient to access the function module if disposed on a side of the rack 800 facing an aisle where the system administrator can easily access the function module (e.g., a front side or rear side of the rack 800). Moreover, although FIG. 8 illustrates that the rack 800 contains only the chassis 100, in other examples, the rack 800 can include other devices such as storage devices, power outputs, switches, and routers.

FIG. 9 is flowchart of a method 900 for hot swapping a component using a function module, according to one embodiment described herein. At block 905, the system administrator removes a cover for a chassis. The system administrator may want to add a new hardware component to the function module which has a connector that is currently unused, replace a faulty hardware component with a new hardware component, or replace a functioning hardware component with an upgraded hardware component. The system administrator can remove the cover by, for example, flipping the cover open using a pivot point, pressing a release button, or other suitable technique.

At block 910, the system administrator slides out the function module. Although the embodiments above use slides to remove the function module from the chassis, other means can be used, such as telescoping rods coupled to the function module and the chassis.

At block 915, the system administrator hot swaps a unit into the function module. That is, a hardware component in the function module (e.g., a GPU card, PCIe card, hard drive, etc.) can be added or removed while the function module receives power. As shown in FIGS. 1 and 2, the cable 115 can provide power and data connectivity to the function module even when removed from the chassis. As such, when replacing one of the hardware components in the function module, the functionality of the other hardware components in the function module is unaffected. Using FIG. 4 as an example, if the first GPU card 415 is being replaced or upgraded (e.g., hot swapped) in the method 900, the blade servers can continue to use the other two GPU cards 415 in the function module.

However, the embodiments herein are not limited to hot swapping the hardware components. For example, if the connector substrate is removed from the function module before replacing or adding new hardware components, doing so may cut-off power from being delivered to the hardware components which means hot swapping is not performed. However, in other embodiments, it may be possible to remove the connector substrate from the function module and still maintain its connection to the cable, thereby making hot swapping possible.

At block 920, the system administrator slides the function module into the chassis and at block 925 replaces or closes the cover. Although not shown, the system administrator may perform other actions such as informing the blade servers that a new hardware component was added or replaced. However, this may be detected automatically by the blade servers as part of performing hot swapping.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality and operation of possible implementations of systems, methods and computer program products according to various embodiments. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In view of the foregoing, the scope of the present disclosure is determined by the claims that follow.

1. A chassis, comprising:
a computing device;
an expansion unit, comprising:
a function module comprising a cage configured to support one or more pluggable hardware components and a fan configured to cool the pluggable hardware components;
a slide, wherein the cage is disposed on the slide, wherein the slide is configured for bidirectional slidable movement allowing the functional module to be moved relative to the chassis; and
a cable coupled to the function module, wherein a length of the cable permits the one or more pluggable hardware components to communicate with the computing device when the function module is slid out from the chassis,
wherein a connector substrate is attached to a first side of the cage, wherein the one or more pluggable hardware components are disposed between the connector substrate and a second side of the cage, wherein the second side is opposite the first side, and
wherein the second side comprises a plurality of slots aligned with a plurality of connectors on the connector substrate, wherein dimensions of the plurality of slots permits a respective one of the one or more pluggable hardware components to pass therethrough.

2. The chassis of claim 1, further comprising:
a plurality of blade servers comprising the computing device, wherein the plurality of blade servers is communicatively coupled to the one or more pluggable hardware components.

3. The chassis of claim 1, further comprising:
a power module, wherein the cable permits the one or more pluggable hardware components to be powered by the power module when the function module is slid out from the chassis.

4. The chassis of claim 1,
wherein the one or more pluggable hardware components plug into the plurality of connectors, wherein the connector substrate is configured to communicatively couple the one or more pluggable hardware components to the cable.

5. (canceled)

6. (canceled)

7. The chassis of claim 4, further comprising:
an interposer coupled to the cable; and
a server interface coupled to the computing device and the interposer.

8. The chassis of claim 7, wherein the interposer is coupled to a first end of the cable while a second end of the cable is coupled to the connector substrate.

9. The chassis of claim 1, further comprising:
a removable cover configured to provide access to the function module when the function module is disposed in the chassis.

10. The chassis of claim 1, wherein the function module comprises:
a fan mounted on the cage, wherein the fan is configured to receive power from the cable and cool the one or more pluggable hardware components.

11. A method, comprising:
moving a cover to access an expansion unit disposed in a chassis, wherein the expansion unit comprises a function module that supports one or more pluggable hardware components and a fan configured to cool the pluggable hardware components, a slide on which is disposed the function module, and a cable coupled to the function module;
sliding the function module out of the chassis, wherein the function module remains connected to the cable to permit the one or more pluggable hardware components to communicate with a computing device in the chassis when the function module is slid out from the chassis; and
plugging at least one pluggable hardware component into the function module,
wherein the function module comprises a connector substrate comprising a plurality of connectors, wherein the one or more pluggable hardware components plug into the plurality of connectors, wherein the connector substrate is configured to communicatively couple the one or more pluggable hardware components to the cable, and
wherein the connector substrate is attached to a first side of a cage in the function module, wherein the one or more pluggable hardware components are disposed between the connector substrate and a second side of the cage, wherein the second side is opposite the first side.

12. The method of claim 11, wherein the chassis comprises a plurality of blade servers which includes the computing device, wherein the plurality of blade servers is communicatively coupled to the one or more pluggable hardware components.

13. The method of claim 11, further comprising:
powering the one or more pluggable hardware components using the cable when the function module is slid out of the chassis.

14. (canceled)

15. (canceled)

16. The method of claim 11, wherein plugging the at least one pluggable hardware component into the function module comprises:
passing the at least one pluggable hardware component through a first slot of a plurality of slots in the second side, wherein the plurality of slots is aligned with the plurality of connectors.

17. The method of claim 11, wherein an interposer is coupled to the cable and a server interface is coupled to the computing device and the interposer.

18. The method of claim 17, wherein the interposer is coupled to a first end of the cable while a second end of the cable is coupled to the connector substrate.

19. The method of claim 11, further comprising:
transmitting power to a fan disposed the function module using the cable, wherein the fan cools the one or more pluggable hardware components.

20. The method of claim 11, wherein plugging the at least one pluggable hardware component into the function module comprises:
hot swapping the at least one pluggable hardware component with a corresponding one of the one or more pluggable hardware components.

21. The chassis of claim 1, wherein the second side opposite the first side is substantially parallel to the first side.

22. The chassis of claim 1, wherein the plurality of slots comprise holes in the second side.
